(19) United States
(12) Patent Application Publication
(10) Pub. No.: US 2024/0096241 A1
(43) Pub. Date: Mar. 21, 2024

(54) DISPLAY APPARATUS

(71) Applicants: NEC Corporation, Minato-ku, Tokyo (JP); NEC Platforms, Ltd., Kawasaki-shi, Kanagawa (JP)

(72) Inventors: Hiroki Sugegaya, Tokyo (JP); Akihiko Onita, Tokyo (JP); Shunsuke Tsuda, Tokyo (JP); Benny Goh, Tokyo (JP); Hiromitsu Nakano, Kanagawa (JP); Kunihiro Akaba, Kanagawa (JP); Kazuhiko Oda, Kanagawa (JP)

(73) Assignees: NEC Corporation, Minato-ku, Tokyo (JP); NEC Platforms, Ltd., Kawasaki-shi, Kanagawa (JP)

(21) Appl. No.: 18/275,130

(22) PCT Filed: Nov. 5, 2021
(86) PCT No.: PCT/JP2021/040761

§ 371 Date: Jul. 31, 2023

(30) Foreign Application Priority Data
Feb. 3, 2021 (JP) 2021-016059

(51) Int. Cl. G09F 3/20; H05K 5/02

(52) U.S. Cl. CPC G09F 3/208; H05K 5/0204

(57) ABSTRACT

A display apparatus (100) includes a shelf tag attachment member (102) being fixed to a front end surface of a product shelf S, and a shelf tag (101) having a display surface (103). The shelf tag (101) is attached to the shelf tag attachment member (102) via a rotation axis A, and is rotatable in a predetermined direction in which the display surface (103) is turned upward. A lower end of the shelf tag (101) is located below a lower surface LS of the product shelf S and a lower end of the shelf tag attachment member (102) in a vertical direction.

### TECHNICAL FIELD

The present invention relates to a display apparatus.

### BACKGROUND ART

For example, a display member described in PTL 1 has been proposed as a display apparatus being attached to a product shelf in order to display a product price or the like.

The display member described in PTL 1 is a member being detachably attached to a product display shelf (hereinafter, also simply referred to as a “shelf”) made of a material to which a magnet adheres, and is constituted of a support plate and a display board. The support plate is detachably attached to a lower surface of the shelf by magnetic force. The display board is attached in such a way as to hang down at a front end of the support plate.

### RELATED DOCUMENT

### Patent Document

PTL 1: Japanese Patent Application Publication No. 2008-83664

### SUMMARY OF THE INVENTION

### Technical Problem

In a display member described in PTL 1, as described above, a support plate is attached to a lower surface of a shelf, and the display member hangs down from a front end of the support plate. According to this configuration, substantially the entire display member is positioned below the lower surface of the shelf, and the display member protrudes significantly below the lower surface of the shelf.

Generally, a fixture on which a product is arranged often includes a plurality of shelves in a vertical direction. In this case, when the display member protrudes more than the lower surface of the shelf, the display member may partially or entirely cover a product arranged on a lower shelf, in front of the product. Herein, the lower shelf is a shelf located below a shelf to which the display member is attached, and the same also applies hereinafter.

Thus, when a product placed on a lower shelf is taken out, the product and a display member may contact with each other, and it may be difficult to take out the product on the lower shelf from the shelf. Moreover, when the product placed on the lower shelf is partially hidden by the display member, there is concern that it becomes difficult for a purchaser to see the product from a front side.

The present invention has been made in view of the circumstances described above, and an object thereof is to provide a display apparatus from which a product is easily taken out. Moreover, another object thereof is to provide a display apparatus in which it is difficult to block visibility of a product.

### Solution to Problem

In order to achieve the above object, a display apparatus according to the present invention includes:
a shelf tag attachment member being fixed to a front end surface of a product shelf; and
a shelf tag having a display surface, wherein
the shelf tag is attached to the shelf tag attachment member via a rotation axis, and is rotatable in a predetermined direction in which the display surface is turned upward, and
a lower end of the shelf tag is located below a lower surface of the product shelf and a lower end of the shelf tag attachment member in a vertical direction.

### Advantageous Effects of Invention

According to the present invention, it becomes possible for a product to be easily taken out. Moreover, it becomes possible to make blocking of visibility of a product difficult.

### BRIEF DESCRIPTION OF THE DRAWINGS

FIG. 1 is a perspective view in which a display apparatus according to one example embodiment of the present invention is seen from a front side.

FIG. 2 is a perspective view in which the display apparatus according to one example embodiment is seen from a rear side.

FIG. 3 is a perspective view in which a shelf tag according to one example embodiment is seen from the rear side.

FIG. 4 is a perspective view in which a shelf tag attachment member according to one example embodiment is seen from the front side.

FIG. 5 is a plan view of the display apparatus according to one example embodiment.

FIG. 6 is a side view illustrating a state where the display apparatus according to one example embodiment is fixed to a product shelf.

FIG. 7 is a side view illustrating a first state where a target product is being taken out in a state where the display apparatus according to one example embodiment is fixed to the product shelf.

FIG. 8 is a side view illustrating a second state where a target product is being taken out in a state where the display apparatus according to one example embodiment is fixed to the product shelf.

FIG. 9 is a side view illustrating a state after a target product is taken out in a state where the display apparatus according to one example embodiment is fixed to the product shelf.

FIG. 10 is a side view illustrating a state where the shelf tag has maximally rotated with respect to the shelf tag attachment member, in the display apparatus according to one example embodiment.

### DESCRIPTION OF EMBODIMENTS

Hereinafter, one example embodiment of the present invention is described with reference to the drawings. Note that, in all of the drawings, a similar component is assigned with a similar reference sign, and description thereof is omitted as appropriate.

### <<Configuration of a Display Apparatus 100>>

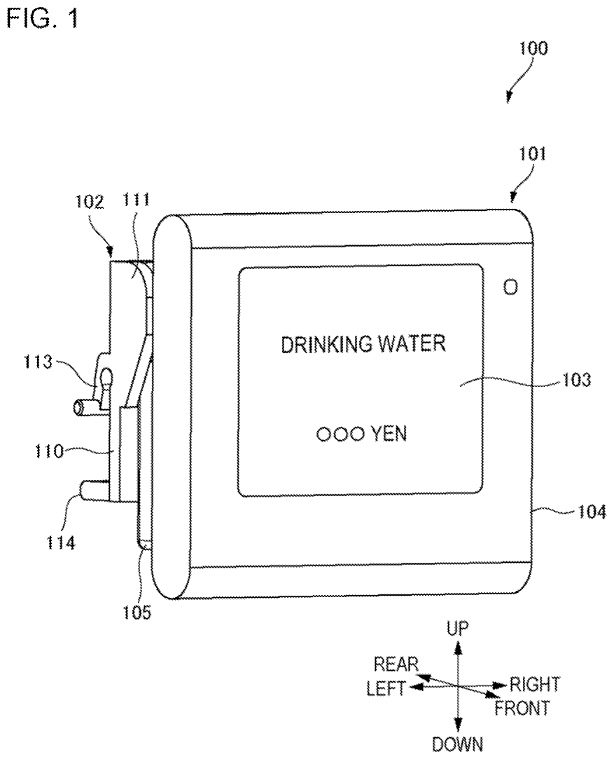

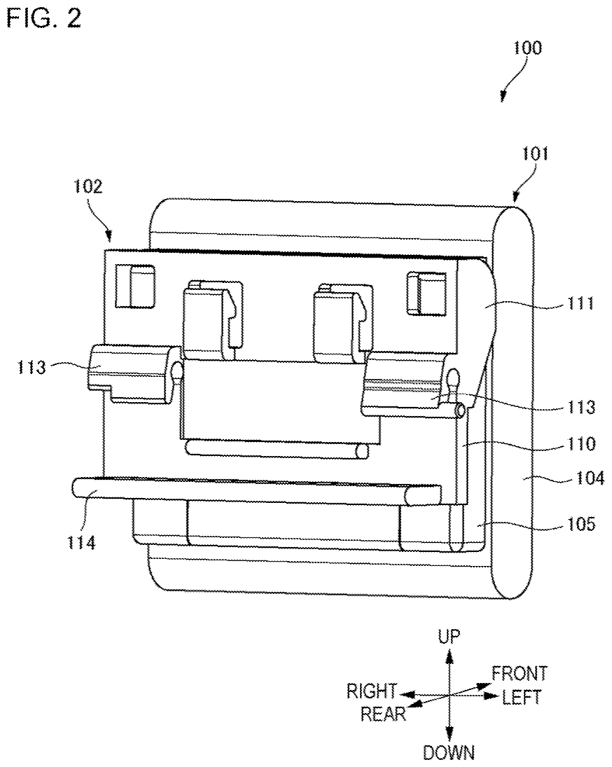

A display apparatus 100 according to one example embodiment of the present invention is an apparatus that is attached, in association with a product C, to a front end surface of a product shelf S on which the product C is displayed, and displays product information such as a product name, a price, and an advertisement of the product C. The display apparatus 100 includes a shelf tag 101 and a shelf tag attachment member 102, as illustrated in FIG. 1 being a front perspective view, and FIG. 2 being a rear perspective view.

The shelf tag 101 is a member that displays product information, and is an electronic shelf tag having a display surface 103. The shelf tag 101 includes, for example, a housing and a liquid crystal display panel, and the display surface 103 in this case is, for example, a display screen of the liquid crystal display panel. Inside the housing of the shelf tag 101, a battery serving as a power supply, a circuit for displaying product information on the display surface 103, and the like are accommodated. The housing of the shelf tag 101 is made of, for example, resin, but may be made of another appropriate material.

In the present example embodiment, a direction is described in such a way that a direction in which the display surface 103 of the display apparatus 100 in a normal state as illustrated in FIGS. 1 and 2 is turned is defined as a front side, and a direction opposite thereto is defined as a “rear side”. Moreover, each of vertical and horizontal directions is defined according to a direction in which the shelf tag 101 in a state of being correctly placed in such a way that product information of the display surface 103 can be correctly viewed is seen from the front side.

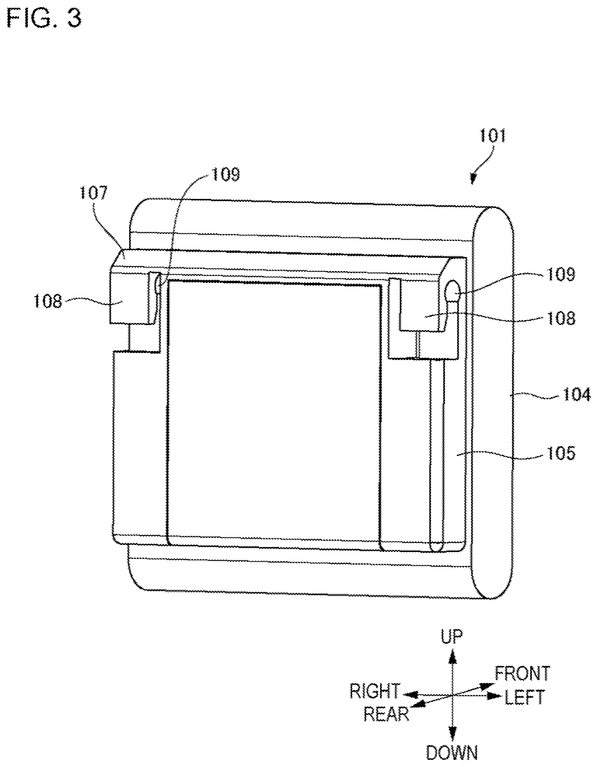

As illustrated in FIGS. 1 to 3, the shelf tag 101 includes a shelf tag body 104 provided with the display surface 103, and a rear protrusion portion 105. Herein, FIG. 3 is a perspective view in which the shelf tag 101 is seen from the rear side.

The shelf tag body 104 substantially is in a flat plate shape having a thickness in a front-rear direction, and each of an upper end surface and a lower end surface is rounded.

The rear protrusion portion 105 is a substantially rectangular-parallelepiped portion protruding rearward from a rear surface of the shelf tag body 104, and includes a first locking portion 107, left and right locking piece portions 108, and left and right hole portions 109.

The first locking portion 107 is a portion forming an inclined surface, and is provided on a rear upper portion of the rear protrusion portion 105. That is to say, the first locking portion 107 is provided at a rear upper portion of the shelf tag 101.

Each of the left and right locking piece portions 108 is a portion being configured in such a way as to hang down from a substantially lower end of the first locking portion 107 downward, and has a substantially rectangular-parallelepiped shape when seen from the rear side.

The left locking piece portion 108 according to the present example embodiment is provided above a left end of the rear protrusion portion 105, and is provided with a gap in a surrounding area (front, right, and lower sides) except for an upper end connected to the first locking portion 107. Thereby, the left locking piece portion 108 is configured in a cantilever beam shape in which an upper end is fixed.

Moreover, the right locking piece portion 108 according to the present example embodiment is provided above a right end of the rear protrusion portion 105, and is provided with a gap in a surrounding area (front, left, and lower sides) except for an upper end connected to the first locking portion 107. Thereby, the right locking piece portion 108 is configured in a cantilever beam shape in which an upper end is fixed, similar to the left locking piece portion 108.

Furthermore, when seen from a lateral side, a front surface of each of the locking piece portions 108 includes a portion (bulging portion) that bulges forward, and, thereby, each of the gaps is configured in such a way as to gradually become narrow from a lower side toward an upper side. Herein, the lateral side is a left side or a right side, and the same also applies hereinafter.

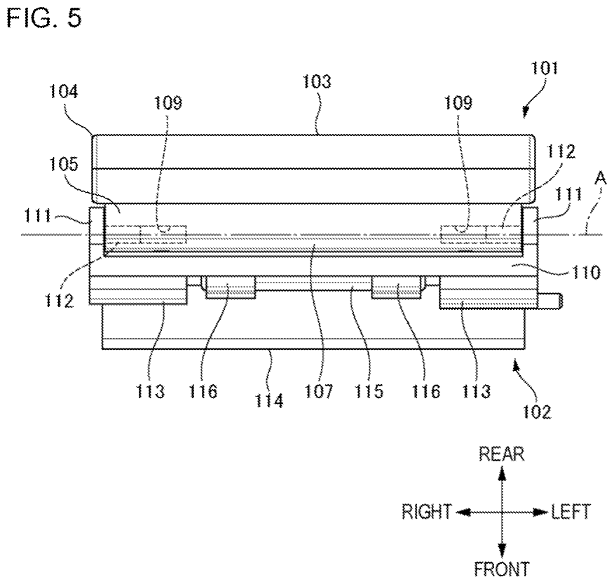

The left and right hole portions 109 each form a through-hole in the horizontal direction being connected to an upper end of each of the gaps in front of the left and right locking piece portions 108. The through-hole formed by each of the left and right hole portions 109 has a substantially columnar shape around a rotation axis A (refer to FIG. 5) extending in the horizontal direction.

When seen from the lateral side, a length (diameter) of the hole portion 109 in a front-rear direction is greater than a length, in the front-rear direction, of the gap located in front of the bulging portion of the locking piece portion 108.

The shelf tag attachment member 102 is a member being fixed to the front end surface of the product shelf S, and the shelf tag 101 is attached to a front side of the shelf tag attachment member 102. The shelf tag attachment member 102 is made of, for example, resin, and, as illustrated in FIGS. 1, 2, and 4, includes a shelf tag attachment portion 110, left and right front protrusion portions 111, left and right shaft portions 112, left and right clip portions 113, a holding plate portion 114, a holding plate connection portion 115, and left and right insertion portions 116.

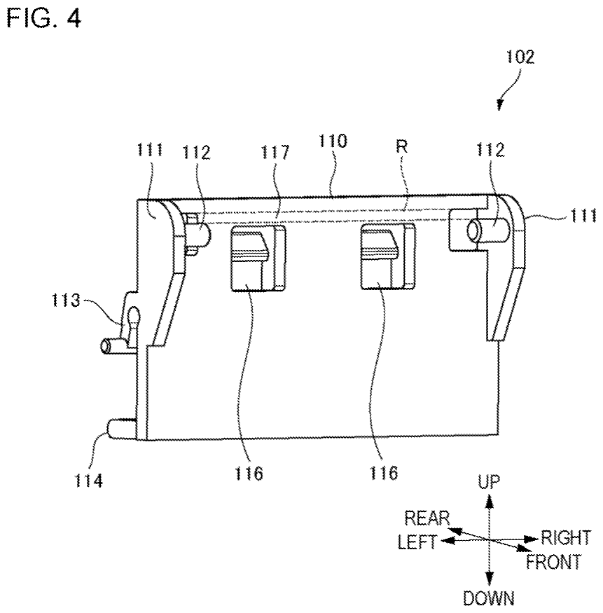

Herein, FIG. 4 is a perspective view in which the shelf tag attachment member 102 is seen from the front side. Moreover, the shelf tag attachment member 102 is made of, for example, resin, but may be made of another appropriate material.

The shelf tag attachment portion 110 is an approximately rectangular flat-plate-shaped portion having a thickness in the front-rear direction. In the present example embodiment, upper and lower ends of the shelf tag attachment portion 110 extend in the horizontal direction, and left and right ends thereof extend in the vertical direction.

The shelf tag attachment portion 110 includes a second locking portion 117 constituting, together with the first locking portion 107, a locking mechanism described later in detail.

The second locking portion 117 according to the present example embodiment is a flat portion surrounded by a substantially rectangular region (a region R indicated by a dotted line in FIG. 4) extending in the horizontal direction in the upper part of the front surface of the shelf tag attachment portion 110. That is to say, the second locking portion 117 is provided at a front upper portion of the shelf tag attachment member 102.

Each of the left and right front protrusion portions 111 is a flat-plate-shaped portion protruding forward from each of the left and right ends of the shelf tag attachment portion 110. Each of the front protrusion portions 111 has a thickness in the horizontal direction.

Specifically, the right front protrusion portion 111 is connected from an upper right end of the shelf tag attachment portion 110 to substantially a center of the right end, and protrudes forward. The left front protrusion portion 111 is connected from a left upper end of the shelf tag attachment portion 110 to substantially a center of the right end, and protrudes forward.

Each upper front end of the front protrusion portion 111 is formed in a substantially arc shape extending smoothly downward, and each lower front end includes a part being inclined in such a way as to protrude forward as the part goes upward.

Each of the left and right shaft portions 112 is a portion being provided on each of the left and right front protrusion portions 111, and extending in the horizontal direction in front of the shelf tag attachment portion 110. Each of the left and right shaft portions 112 has a thin columnar shape around the rotation axis A (refer to FIG. 5) extending in the horizontal direction.

Specifically, the right shaft portion 112 extends leftward from a left surface of the right front protrusion portion 111. The left shaft portion 112 extends rightward from a right surface of the left front protrusion portion 111. When seen from the lateral side, a diameter of each of the left and right shaft portions 112 is slightly smaller than a diameter of each of the left and right hole portions 109. Thereby, as to each of the left and right shaft portions 112 and the left and right hole portions 109, the shaft portion 112 can loosely fit into the hole portion 109.

Each of the left and right clip portions 113 is provided on a rear surface of the shelf tag attachment portion 110, and forms a gap being open downward, between each of the left and right clip portions 113 and the shelf tag attachment portion 110. Upper ends of the gaps formed by the left and right clip portions 113 are substantially at the same position in the vertical direction.

The holding plate portion 114 is a flat-plate-shaped portion protruding rearward from a substantially lower end of the shelf tag attachment portion 110 and extending in the horizontal direction. The holding plate portion 114 is in a flat plate shape with an upper surface and a lower surface parallel to each other, and is preferably substantially perpendicular to the rear surface of the shelf tag attachment portion 110. Thereby, it becomes easy to remove from a mold, and it becomes possible to make manufacturing easy.

The holding plate connection portion 115 connects a front end of the holding plate portion 114 and the rear surface of the shelf tag attachment portion 110. The holding plate connection portion 115 has a length (thickness) in the vertical direction being thinner than that of the holding plate portion 114, and is provided with a plurality of through-holes (long holes being long in left and right directions in the present example embodiment) penetrating in the vertical direction.

By connecting the holding plate portion 114 to the rear surface of the shelf tag attachment portion 110 via the holding plate connection portion 115, the holding plate portion 114 can be easily separated from the shelf tag attachment portion 110. Specifically, for example, by swinging the holding plate portion 114 up and down several times around the holding plate connection portion 115 in a state where the shelf tag attachment portion 110 is held, the holding plate connection portion 115 causes brittle fracture, and the holding plate portion 114 can be easily separated from the shelf tag attachment portion 110.

For example, depending on a shape of the product shelf S to which the shelf tag attachment member 102 is attached, the holding plate portion 114 may interfere, and it may be difficult to fix the shelf tag attachment member 102 to the product shelf S. In such a case, the holding plate portion 114 may be separated from the shelf tag attachment portion 110.

The left and right insertion portions 116 are provided on the rear surface of the shelf tag attachment portion 110, and are provided above the clip portion 113 in the vertical direction. Each of the left and right insertion portions 116 forms a notch being open upward. Lower ends of the notches formed by the left and right insertion portions 116 are substantially at the same position in the vertical direction.

By inserting, from above, a display board into such notches formed by the left and right insertion portions 116, the display board can be held by the shelf tag attachment member 102. The display board is a relatively thin sheet-shaped member made of paper, resin, or the like for displaying an advertisement or the like of the product C.

### <<Assembly Method of the Display Apparatus 100>>

The display apparatus 100 is assembled by attaching the shelf tag 101 to the shelf tag attachment member 102. From now on, an assembly method of the display apparatus 100 is described.

The shelf tag 101 is positioned between the left and right front protrusion portions 111 from a front upper side of the shelf tag attachment member 102. Then, the shelf tag 101 is moved downward with respect to the shelf tag attachment member 102 in such a way as to cause each of the left and right shaft portions 112 to pass through the gap provided in front of each of the left and right locking piece portions 108.

Since each of the locking piece portions 108 includes, in the front surface, a bulging portion bulging forward as described above, each of the shaft portions 112 contacts the bulging portion when the shelf tag 101 is moved downward with respect to the shelf tag attachment member 102. Each of the locking piece portions 108 has elasticity, and, therefore, when the shelf tag 101 is pushed further downward with respect to the shelf tag attachment member 102 after each of the shaft portions 112 contacts the bulging portion, each of the locking piece portions 108 bends rearward due to force received from the shaft portion 112 in contact. Thereby, each of the left and right shaft portions 112 passes through the bulging portion, and is positioned in each of the left and right hole portions 109.

When each of the left and right shaft portions 112 is positioned in each of the left and right hole portions 109, each of the locking piece portions 108 being bent rearward returns to an original position due to the elasticity thereof. A part under each of the shaft portions 112 is closed by the bulging portion that has returned to the original position, and each of the left and right shaft portions 112 is loosely fitted into each of the left and right hole portions 109 (refer to a plan view in FIG. 5). Thereby, the shelf tag 101 is attached to the shelf tag attachment member 102, and the display apparatus 100 is assembled.

In the display apparatus 100 assembled in this way, since each of the left and right shaft portions 112 is loosely fitted into each of the left and right hole portions 109 as described above, the shelf tag 101 can rotate around the rotation axis A in a predetermined direction in which the display surface 103 is turned upward. That is to say, the shelf tag 101 is attached to the shelf tag attachment member 102 via the rotation axis A, and is rotatable in a predetermined direction in which the display surface 103 is turned upward.

Moreover, in the display apparatus 100, the lower end of the shelf tag 101 is located below a lower end of the shelf tag attachment member 102 in the vertical direction. Thereby, when the product C or the like contacts a vicinity of the lower end of the shelf tag 101 from the rear side, the shelf tag 101 can rotate around the rotation axis A in a predetermined direction in which the display surface 103 is turned upward.

### <<Fixing Method of the Display Apparatus 100 to the Product Shelf S>>

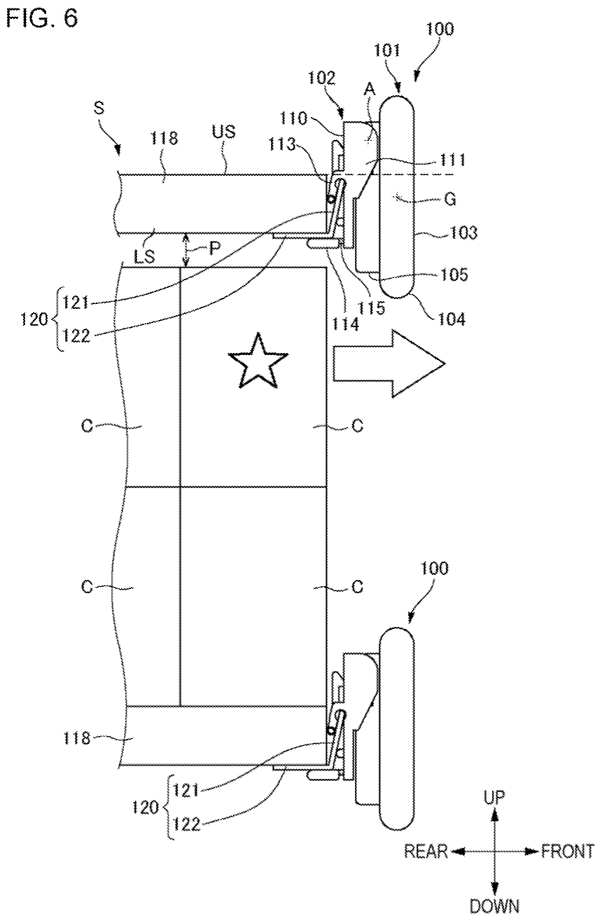

As illustrated in the side view in FIG. 6, the display apparatus 100 is fixed to the front end surface of the product shelf S by fixing the shelf tag attachment member 102 to the front end surface of the product shelf S. From now on, a fixing method of the display apparatus 100 to the product shelf S is described.

The product shelf S to which the display apparatus 100 is fixed includes a shelf 118 on which the product C is laid out, and an L-shaped plate 120 disposed in front of the shelf 118 and in front of a lower surface thereof.

The shelf 118 is a flat-plate-shaped portion on which the product C are laid out and put. The shelf 118 is preferably made of metal, resin, wood, or the like.

The L-shaped plate 120 is a plate-shaped member bent in an L-shape when seen from the lateral side, and is integrally formed of metal, resin, or the like. The L-shaped plate 120 includes a front plate 121 arranged in front of the shelf 118, and a fixing portion 122 for fixing the L-shaped plate 120 to the shelf 118.

The front plate 121 is arranged substantially parallel to the front end surface of the shelf 118 with a relatively narrow gap. The fixing portion 122 is a flat plate-shaped portion arranged on a lower front side of the shelf 118, and is fixed to the lower surface of the shelf 118 by an appropriate method such as screwing, adhesive bonding, or adhesion with a double-sided tape.

The display apparatus 100 is arranged on the product shelf S from a front upper side in such a way that an upper end of the front plate 121 is located at a lower end of the gap between each of the left and right clip portions 113 and the shelf tag attachment portion 110.

While the front plate 121 is bent in such a way as to curve forward by elasticity thereof, a rear end of the holding plate portion 114 is positioned below a lower surface LS of the product shelf S. Further, the display apparatus 100 is moved with respect to the product shelf S in such a way that the front plate 121 moves upward in the gap between each of the left and right clip portions 113 and the shelf tag attachment portion 110, and the rear end of the holding plate portion 114 moves further rearward below the lower surface LS.

By arranging the display apparatus 100 with respect to the product shelf S in this way, the front plate 121 is caught between each of the left and right clip portions 113 and the shelf tag attachment portion 110, and the upper surface of the holding plate portion 114 and the lower surface LS of the product shelf S contact with each other. Thereby, the display apparatus 100 is fixed to the product shelf S. Note that, the display apparatus 100 may be slidingly movable in the horizontal direction with respect to the product shelf S in a fixed state.

As can be understood by referring to FIG. 6, the lower end of the shelf tag 101 is located below the lower surface LS of the product shelf S in the vertical direction. Since the display apparatus 100 is fixed to the front end surface of the product shelf S, an amount of protrusion below the lower surface LS can be reduced as compared with, for example, a case where the display apparatus 100 is attached to the product shelf S in such a way that the entire shelf tag 101 hangs down from the lower surface LS of the product shelf S. Thus, when seen from the front side, a range hiding the product C arranged on the product shelf S below the product shelf S to which the display apparatus 100 is fixed can be reduced. Therefore, it becomes possible to make blocking of visibility of the product C difficult.

Moreover, an upper end of the display apparatus 100 is located above an upper surface US of the product shelf S in the vertical direction. Since the display apparatus 100 is fixed to the front end surface of the product shelf S, an amount of protrusion above the upper surface US can be reduced as compared with, for example, a case where the display apparatus 100 is erected and fixed on the product shelf S. Thus, when seen from the front side, a range hiding the product C arranged on the product shelf S to which the display apparatus 100 is fixed can be reduced. Thus, it becomes possible to make blocking of visibility of the product C difficult.

Note that, a fixing method described herein is one example for fixing the display apparatus 100 to the front end surface of the product shelf S, and a fixing method may be changed as appropriate as long as the display apparatus 100 can be fixed to the front end surface of the product shelf S. For example, a form in which the display apparatus 100 is fitted into the product shelf S may be changed as appropriate, and, further, the display apparatus 100 may be fixed to the product shelf S by screwing, adhesive bonding, adhesion, attraction by magnetic force, or the like.

### <<Operation of the Display Apparatus 100>>

From now on, an operation of the display apparatus 100 when the product C is taken out from the product shelf S is described with reference to FIGS. 6 to 9.

Herein, a case where the product C to be taken out from the product shelf S (hereinafter, the product C to be taken out from the product shelf S is also referred to as a “target product C”) is the product C marked with a star among the products C illustrated in FIG. 6 is described as an example. Moreover, a person who takes out the target product C from the product shelf S is typically a clerk of a store selling the target product C, or a purchaser of the target product C. An example in which a purchaser takes out the target product C from the product shelf S is described below.

As illustrated in FIG. 6, on the product shelf S below the product shelf S to which the display apparatus 100 is fixed, the products C being stacked in two tiers, one above the other, are laid out from the front side toward the rear side, and the target product C is the product C arranged on the frontmost side in an upper tier. When taking out the target product C from the product shelf S, a purchaser moves the target product C forward.

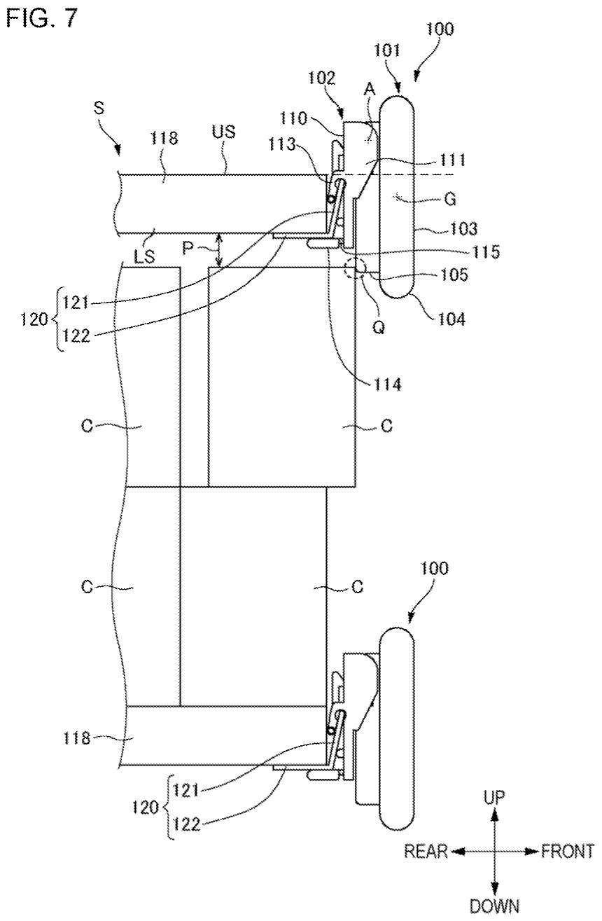

As described above, the lower end of the shelf tag 101 is located below the lower surface LS of the product shelf S and the lower end of the shelf tag attachment member 102 in the vertical direction. Thus, even when there is a gap P between the target product C and the lower surface LS of the product shelf S, there is a possibility that a vicinity of the lower end of the shelf tag 101 protruding downward from the lower surface LS contacts the target product C that has moved forward, as illustrated in a part surrounded by a dotted line Q in FIG. 7.

Herein, FIG. 7 is a side view illustrating a first state where the target product C is being taken out in a state where the display apparatus 100 is fixed to the product shelf S. The first state is a state where the vicinity of the lower end of the shelf tag 101, the target product C, and contact contact with each other.

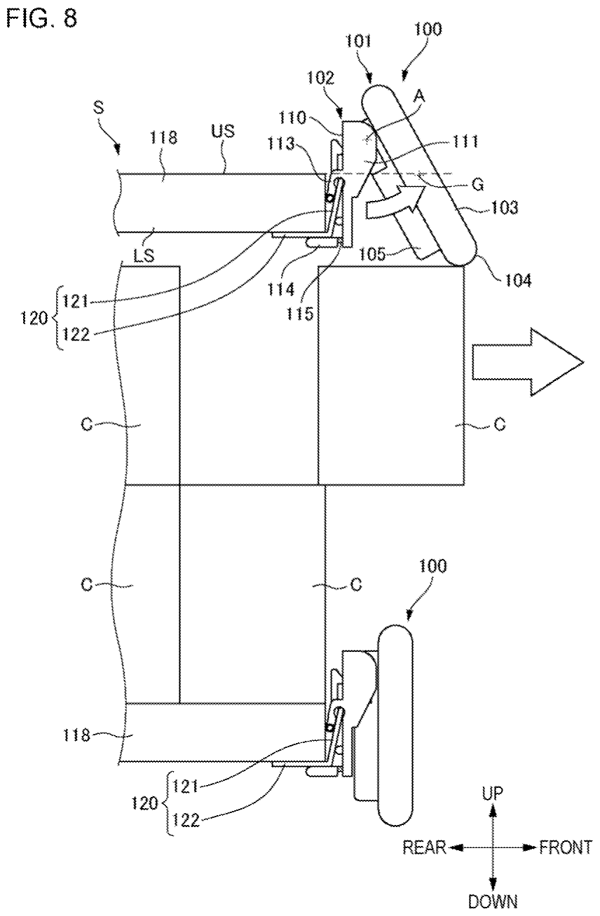

When a purchaser moves the target product C further forward, the vicinity of the lower end of the shelf tag 101 is pushed by the target product C from the rear side at a point where the vicinity of the lower end of the shelf tag 101 contacts the target product C. Thereby, the shelf tag 101 rotates around the rotation axis A in a predetermined direction (in FIG. 8, counterclockwise as indicated by an arrow in FIG. 8) in which the display surface 103 is turned upward as illustrated in FIG. 8. Thus, since the target product C can pass under the shelf tag 101 even after the shelf tag 101 and the target product C contact with each other, the purchaser can easily move the target product C forward.

Herein, FIG. 8 is a side view illustrating a second state where the target product C is being taken out in a state where the display apparatus 100 is fixed to the product shelf S. The second state is one state where the target product C is passing under the shelf tag 101.

Moreover, as can be understood by referring to FIG. 6, a center of gravity G of the shelf tag 101 is located below the rotation axis A in a state before the shelf tag 101 rotates with respect to the shelf tag attachment member 102 in a predetermined direction. Thus, as illustrated in FIG. 8, while the target product C passes under the shelf tag 101, the shelf tag 101 that has rotated with respect to the shelf tag attachment member 102 in a predetermined direction will rotate, due to own weight thereof, in a direction opposite to the predetermined direction.

As a result, while passing under the shelf tag 101, the target product C contacts the vicinity of the lower end of the shelf tag 101, and receives force from the shelf tag 101. However, the force that the target product C receives from the shelf tag 101 is force being substantially relevant to weight of the shelf tag 101, is therefore relatively small, and is not of such magnitude as to damage the target product C. Therefore, it becomes possible to make takeout of the target product C easy.

Further, as can be understood by referring to FIG. 8, the rotation axis A is located above the upper surface US of the product shelf S in the vertical direction. Note that, the rotation axis A may be at the same position as the upper surface US of the product shelf S in the vertical direction.

In this way, by setting a position of the rotation axis A in the vertical direction with respect to the upper surface US of the product shelf S, a rotation angle of the shelf tag 101 in a predetermined direction for passing the target product C can be reduced as compared with a case where the rotation axis A is located below the upper surface US of the product shelf S. Thus, it becomes easy for a purchaser to take out the target product C as compared with a case where the shelf tag 101 needs to be largely rotated in order to take out the target product C. Therefore, it becomes possible to make takeout of the target product C easier.

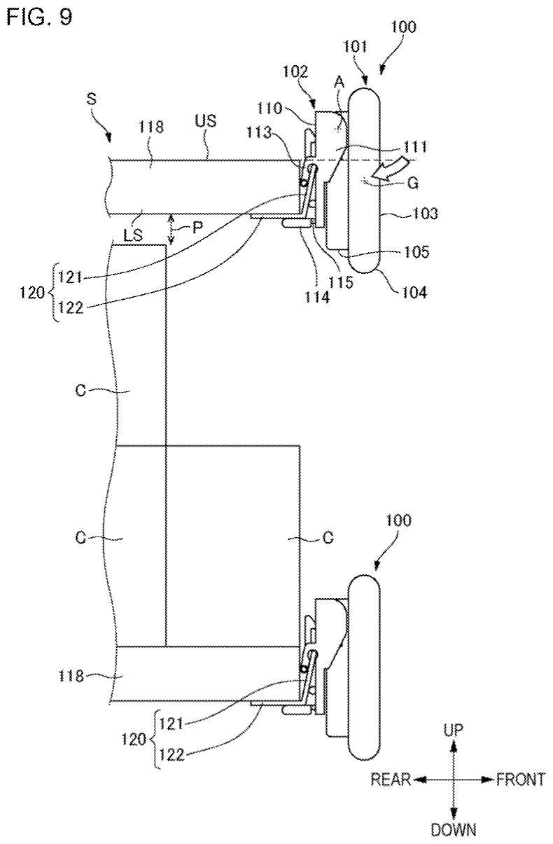

When the entire target product C passes under the shelf tag 101, takeout of the target product C from the product shelf S is completed. Thereafter, as illustrated in FIG. 9, the shelf tag 101 rotates, due to own weight thereof, in a direction (in FIG. 9, clockwise as indicated by an arrow in FIG. 9) opposite to a predetermined direction, and returns to an original position (a position of the shelf tag 101 illustrated in FIG. 6) before rotating in the predetermined direction. Therefore, a purchaser can save a trouble of returning a position of the shelf tag 101 to the original position, and it becomes possible to improve convenience.

Herein, as to the target product C, a case where the product C arranged on the frontmost side of the upper tier among the products C arranged under the product shelf S to which the display apparatus 100 is fixed is taken out has been described as an example. This is because it is considered that the product C arranged at the position easily contacts the shelf tag 101. It becomes easy to take out the product C by rotating the shelf tag 101, and the same also applies even to a case where another product C contacts the shelf tag 101 when taken out.

<<A Rotatable Range of the Shelf Tag 101 with Respect to the Shelf Tag Attachment Member 102>>

In the display apparatus 100 according to the present example embodiment, a rotatable range of the shelf tag 101 with respect to the shelf tag attachment member 102 is restricted by the locking mechanism composed of the first locking portion 107 and the second locking portion 117. In other words, the display apparatus 100 includes a locking mechanism for restricting a range in which the shelf tag 101 rotates with respect to the shelf tag attachment member 102 in a predetermined direction. The shelf tag 101 is rotatable until the lower end of the shelf tag 101 is located at the same position as the lower surface of the product shelf S or above the lower surface in the vertical direction.

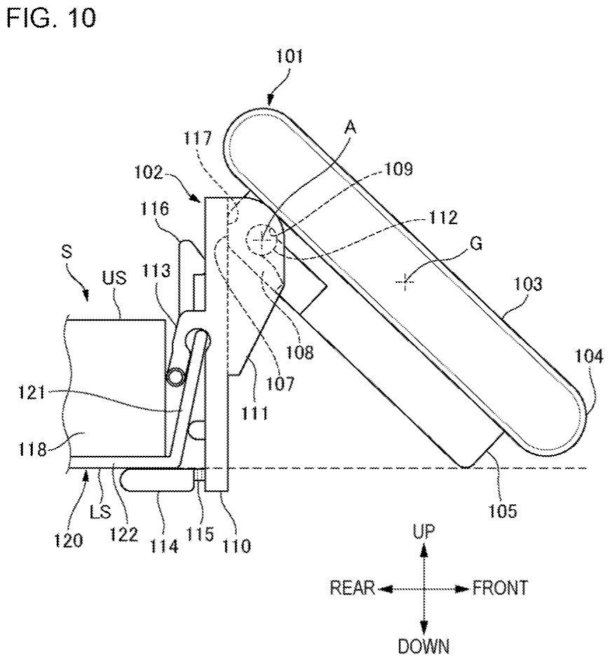

FIG. 10 is a side view illustrating a state where the shelf tag 101 has maximally rotated with respect to the shelf tag attachment member 102 in a predetermined direction. The figure illustrates an example of being rotatable until the lower end of the shelf tag 101 is located substantially at the same position as the lower surface of the product shelf S in the vertical direction.

As illustrated in the figure, when the shelf tag 101 maximally rotates with respect to the shelf tag attachment member 102 in a predetermined direction, the first locking portion 107 and the second locking portion 117 contact with each other, and, thereby, rotation of the shelf tag 101 with respect to the shelf tag attachment member 102 is restricted.

By providing the locking mechanism, a rotation range of the shelf tag 101 with respect to the shelf tag attachment member 102 can be restricted. Thereby, it becomes possible to prevent damage to the display apparatus 100 resulting from excessive rotation of the shelf tag 101 with respect to the shelf tag attachment member 102, in such a case where the product C being taken out from the product shelf S collides with the shelf tag 101.

Further, in the present example embodiment, when the shelf tag 101 has rotated in a predetermined direction by a maximum angle, the first locking portion 107 and the second locking portion 117 contact with each other on a surface extending substantially in the horizontal direction. That is to say, in the locking mechanism according to the present example embodiment, the first locking portion 107 and the second locking portion 117 contact with each other on a surface when the shelf tag 101 has rotated in a predetermined direction by the maximum angle, and, thereby, a range in which the tag 101 rotates with respect to the shelf tag attachment member 102 in a predetermined direction is restricted.

In this way, when rotation of the shelf tag 101 with respect to the shelf tag attachment member 102 is restricted, the first locking portion 107 and the second locking portion 117 contact with each other on a surface, and, thereby, force applied to the first locking portion 107 and the second locking portion 117 is dispersed. Thereby, it becomes possible to more reliably prevent damage to the display apparatus resulting from excessive rotation of the shelf tag 101 with respect to the shelf tag attachment member 102.

Further, the shelf tag 101 is rotatable until the lower end of the shelf tag 101 is located at the same position as the lower surface of the product shelf S in the vertical direction (refer to FIG. 10), or the lower end of the shelf tag 101 is located above the lower surface of the product shelf S. Thereby, even when the product C arranged under the product shelf S to which the display apparatus 100 is fixed is arranged with almost no gap between the product C and the lower surface LS of the product shelf S, the product C can be taken out. Therefore, regardless of how the product C is displayed, it becomes possible to make takeout of the target product C easy.

Further, as illustrated in FIG. 10, the center of gravity G is located below the rotation axis A even in a state where the shelf tag 101 has maximally rotated with respect to the shelf tag attachment member 102 in a predetermined direction. That is to say, the locking mechanism restricts a range in which the shelf tag 101 rotates with respect to the shelf tag attachment member 102 in a predetermined direction, in a range in which the center of gravity G of the shelf tag 101 is located below the rotation axis A in the vertical direction.

Even after the shelf tag 101 has maximally rotated with respect to the shelf tag attachment member 102 in a predetermined direction, the shelf tag 101 can reliably return, due to own weight thereof, to an original position (refer to FIG. 9) before rotation. Therefore, a purchaser or the like can save a trouble of returning a position of the shelf tag 101 to the original position, and it becomes possible to improve convenience.

The rotation axis A is provided in front of the shelf tag attachment member 102. Thus, even when the shelf tag 101 has maximally rotated in a predetermined direction in which the display surface 103 is turned upward, the shelf tag 101 does not protrude rearward from the upper rear end of the shelf tag attachment member 102 (in the present example embodiment, the rear surface of the shelf tag attachment portion 110) in the front-rear direction, as illustrated in FIG. 10. That is to say, the locking mechanism restricts a range in which the shelf tag 101 rotates with respect to the shelf tag attachment member 102 in a predetermined direction in which the display surface 103 is turned upward, in a range in which the shelf tag 101 does not protrude rearward from the rear end of the shelf tag attachment member 102 in the front-rear direction.

Thereby, when the shelf tag 101 has rotated in a predetermined direction in which the display surface 103 is turned upward, contact with the product C arranged on the product shelf S to which the display apparatus 100 is attached can be prevented. Therefore, it becomes possible to hardly damage the product C because of rotation of the shelf tag 101.

As described above so far, with the display apparatus 100 according to the present example embodiment, it becomes possible to make takeout of a product easy. Moreover, it becomes possible to make blocking of visibility of a product difficult.

The present invention is not limited to the example embodiment described so far, and the example embodiment may be modified as follows.

### Modified Example 1

In the example embodiment, a case where a shelf tag 101 is an electronic shelf tag has been described as an example. However, the shelf tag 101 is not limited to an electronic shelf tag, and may be a member that displays, on a display surface 103, product information printed on paper or the like. The shelf tag 101 in this case may be composed of, for example, a piece of paper on which product information is printed, and a resin member that holds the piece of paper. This modified example also provides an advantageous effect similar to that according to the example embodiment.

### Modified Example 2

In the example embodiment, an example in which a holding plate portion 114 is connected to a rear surface of a shelf tag attachment portion 110 via a holding plate connection portion 115 being provided with a plurality of long holes and being thinner than the holding plate portion 114 has been described. However. The holding plate connection portion 115 may be configured in such a way that the holding plate portion 114 is separable from the shelf tag attachment portion 110, and a configuration of the holding plate connection portion 115 is not limited thereto.

For example, as long as the holding plate connection portion 115 is thinner than the holding plate portion 114, the holding plate connection portion 115 may not be provided with a through-hole. When a through-hole is provided in the vertical direction, the through-hole is not limited to a large long hole being long in the horizontal direction as in the example embodiment, and may be a relatively small hole having a substantially columnar shape or the like in which a length in the horizontal direction is shorter than that in the example embodiment. When a small through-hole is adopted, perforations may be provided in the holding plate connection portion 115 by providing a plurality of through-holes side by side in the horizontal direction at relatively short intervals.

The present modified example also provides an advantageous effect similar to that according to the example embodiment.

### Modified Example 3

In the example embodiment, an example in which a shelf tag 101 is attached to a shelf tag attachment member 102 via a rotation axis A by fitting of a hole portion 109 of the shelf tag 101 and a shaft portion 112 of the shelf tag attachment member 102 has been described. However, the shelf tag 101 may be attached to the shelf tag attachment member 102 via the rotation axis A, and be rotatable in a predetermined direction in which a display surface 103 is turned upward.

For example, one or both of the left and right hole portions 109 may not penetrate, and may be a hole portion having a depth (length in the horizontal direction), a recessed portion forming a relatively shallow recess, or the like. Moreover, one or both of the left and right shaft portions 112 are not limited to a columnar shape, and may be a projection or the like.

For example, the hole portion 109 may be provided in the shelf tag attachment member 102, and the shaft portion 112 may be provided in the shelf tag 101.

The present modified example also provides an advantageous effect similar to that according to the example embodiment.

### Modified Example 4

The example embodiment has been described by an example in which a locking mechanism is formed of a first locking portion 107 forming an inclined surface provided on a rear upper portion of a rear protrusion portion 105, and a second locking portion 117 being a planar part in a front upper portion of a shelf tag attachment portion 110, and the locking portions 107 and 117 contact with each other on a surface when a shelf tag 101 has maximally rotated in a predetermined direction. A configuration of the locking mechanism is not limited thereto.

For example, the first locking portion 107 may be provided in a rear upper portion of the shelf tag 101, or may be provided in a rear upper portion of a shelf tag body 104 and the portion may form an inclined surface. In this case, the shelf tag attachment portion 110 may extend further upward than in the example embodiment in such a way as to contact with the first locking portion 107 when the shelf tag 101 has maximally rotated in a predetermined direction. Moreover, the second locking portion 117 in this case may be a planar part provided on a front side of an extending part of the shelf tag attachment portion 110. This also provides an advantageous effect similar to that according to the example embodiment.

For example, the inclined surface may be provided on a front upper portion of the shelf tag attachment member 102. In this case, the first locking portion 107 may be a planar part of a rear upper portion of the shelf tag 101. Moreover, the second locking portion 117 may be a portion that forms the inclined surface provided in the front upper portion of the shelf tag attachment portion 110. This also provides an advantageous effect similar to that according to the example embodiment.

For example, the first locking portion 107 and the second locking portion 117 may be configured in such a way as to contact with each other linearly or at a plurality of points rather than on a surface when the shelf tag 101 has maximally rotated in a predetermined direction. Thereby, a rotatable range of the shelf tag 101 with respect to the shelf tag attachment member 102 can also be restricted. Thus, it becomes possible to prevent damage to a display apparatus 100 resulting from excessive rotation of the shelf tag 101 with respect to the shelf tag attachment member 102, in such a case where a product C being taken out from a product shelf S collides with the shelf tag 101.

### Modified Example 5

In the example embodiment, an example in which, when a shelf tag 101 has maximally rotated in a predetermined direction in which a display surface 103 is turned upward, the shelf tag 101 does not protrude rearward from an upper rear end of a shelf tag attachment member 102 in a front-rear direction has been described. However, when the shelf tag 101 has maximally rotated in a predetermined direction in which the display surface 103 is turned upward, the shelf tag 101 may protrude rearward from the upper rear end of the shelf tag attachment member 102 in the front-rear direction.

Even in this case, by providing a rotation axis A in front of the shelf tag attachment member 102, an amount in which the shelf tag 101 protrudes rearward from the rear end of the shelf tag attachment member 102 when the shelf tag 101 has maximally rotated in a predetermined direction can be reduced. Therefore, it becomes possible to reduce a possibility of damaging a product C because of rotation of the shelf tag 101.

Although the example embodiment and modified examples of the present invention have been described above, the present invention is not limited thereto. For example, the present invention also includes a form in which some or all of the example embodiment and the modified examples described so far are appropriately combined, and a form in which the combination form is appropriately modified.

Moreover, one means or all the means described in the above example embodiment and modified examples can also be described as, but are not limited to, the following supplementary notes.
1. A display apparatus including:
   a shelf tag attachment member being fixed to a front end surface of a product shelf; and
   a shelf tag having a display surface, wherein
   the shelf tag is attached to the shelf tag attachment member via a rotation axis, and is rotatable in a predetermined direction in which the display surface is turned upward, and
   a lower end of the shelf tag is located below a lower surface of the product shelf and a lower end of the shelf tag attachment member in a vertical direction.
2. The display apparatus according to supplementary note 1, wherein
   the shelf tag is rotatable until the lower end of the shelf tag is located at a same position as a lower surface of the product shelf in a vertical direction or above the lower surface.
3. The display apparatus according to supplementary note 1 or 2, wherein
   a center of gravity of the shelf tag is located below the rotation axis in a vertical direction.
4. The display apparatus according to any one of supplementary notes 1 to 3, wherein
   the rotation axis is located at a same position as an upper surface of the product shelf or above the upper surface in a vertical direction.
5. The display apparatus according to any one of supplementary notes 1 to 4, further including
   a locking mechanism for restricting a range in which the shelf tag rotates with respect to the shelf tag attachment member in the predetermined direction.
6. The display apparatus according to supplementary note 5, wherein
   the locking mechanism is constituted of a first locking portion provided on a rear upper portion of the shelf tag, and a second locking portion provided on a front upper portion of the shelf tag attachment portion, the first locking portion and the second locking portion contact with each other on a surface when the shelf tag has maximally rotated in the predetermined direction, and, thereby, the locking mechanism restricts a range in which the shelf tag rotates with respect to the shelf tag attachment member in the predetermined direction.
7. The display apparatus according to supplementary note 5 or 6, wherein
   the locking mechanism restricts a range in which the shelf tag rotates with respect to the shelf tag attachment member in the predetermined direction, in a range in which a center of gravity of the shelf tag is located below the rotation axis in a vertical direction.
8. The display apparatus according to any one of supplementary notes 5 to 7, wherein
   the rotation axis is provided in front of the shelf tag attachment member, and
   the locking mechanism restricts a range in which the shelf tag rotates with respect to the shelf tag attachment member in the predetermined direction, in a range in which a rear end of the shelf tag does not protrude rearward from an upper rear end of the shelf tag attachment member in a front-rear direction.

This application is based upon and claims the benefit of priority from Japanese patent application No. 2021-016059, filed on Feb. 3, 2021, the disclosure of which is incorporated herein in its entirety by reference.

### REFERENCE SIGNS LIST

100 Display apparatus
101 Shelf tag
102 Shelf tag attachment member
103 Display surface
104 Shelf tag body
105 Rear protrusion portion
107 First locking portion
108 Locking piece portion
109 Hole portion
110 Shelf tag attachment portion
111 Front protrusion portion
112 Shaft portion
113 Clip portion
114 Holding plate portion
115 Holding plate connection portion
116 Insertion portion
117 Second locking portion
118 Shelf
120 L-shaped plate
121 Front plate
122 Fixing portion
A Rotation axis
C Product
G Center of gravity
P Gap
S Product shelf
US Upper surface of product shelf
LS Lower surface of product shelf

What is claimed is:

1. A display apparatus comprising:
a shelf tag attachment member being fixed to a front end surface of a product shelf; and
a shelf tag having a display surface, wherein
the shelf tag is attached to the shelf tag attachment member via a rotation axis, and is rotatable in a predetermined direction in which the display surface is turned upward, and
a lower end of the shelf tag is located below a lower surface of the product shelf and a lower end of the shelf tag attachment member in a vertical direction.

2. The display apparatus according to claim 1, wherein
the shelf tag is rotatable until the lower end of the shelf tag is located at a same position as a lower surface of the product shelf in a vertical direction or above the lower surface.

3. The display apparatus according to claim 1, wherein
a center of gravity of the shelf tag is located below the rotation axis in a vertical direction.

4. The display apparatus according to claim 1, wherein
the rotation axis is located at a same position as an upper surface of the product shelf or above the upper surface in a vertical direction.

5. The display apparatus according to claim 1, further comprising
a locking mechanism for restricting a range in which the shelf tag rotates with respect to the shelf tag attachment member in the predetermined direction.

6. The display apparatus according to claim 5, wherein
the locking mechanism is constituted of a first locking portion provided on a rear upper portion of the shelf tag, and a second locking portion provided on a front upper portion of the shelf tag attachment portion, the first locking portion and the second locking portion contact with each other on a surface when the shelf tag has maximally rotated in the predetermined direction, and, thereby, the locking mechanism restricts a range in which the shelf tag rotates with respect to the shelf tag attachment member in the predetermined direction.

7. The display apparatus according to claim 5, wherein
the locking mechanism restricts a range in which the shelf tag rotates with respect to the shelf tag attachment member in the predetermined direction, in a range in which a center of gravity of the shelf tag is located below the rotation axis in a vertical direction.

8. The display apparatus according to claim 5, wherein
the rotation axis is provided in front of the shelf tag attachment member, and
the locking mechanism restricts a range in which the shelf tag rotates with respect to the shelf tag attachment member in the predetermined direction, in a range in which a rear end of the shelf tag does not protrude rearward from an upper rear end of the shelf tag attachment member in a front-rear direction.
